(19) United States
(12) Patent Application Publication
(10) Pub. No.: US 2026/0239994 A1
(43) Pub. Date: Aug. 13, 2026

(54) INTERPOSER SUBSTRATE AND SEMICONDUCTOR PACKAGE INCLUDING THE SAME

(71) Applicant: SAMSUNG ELECTRONICS CO., LTD., Suwon-si (KR)

(72) Inventors: Yongjae KIM, Suwon-si (KR); Seong Yeon PARK, Suwon-si (KR); Kahyun SUN, Suwon-si (KR); Wongu LEE, Suwon-si (KR)

(73) Assignee: SAMSUNG ELECTRONICS CO., LTD., Suwon-si (KR)

(21) Appl. No.: 19/371,712

(22) Filed: Oct. 28, 2025

(30) Foreign Application Priority Data
Feb. 12, 2025 (KR) 10-2025-0018053

(51) Int. Cl. H10W 46/00; H10W 42/00; H10W 70/63; H10W 70/65; H10W 90/00; H10W 40/00; H10W 74/10; H10W 74/15

(52) U.S. Cl. CPC H10W 46/00; H10W 42/121; H10W 70/635; H10W 70/65; H10W 90/701; H10W 40/00; H10W 46/401; H10W 74/131; H10W 74/15; H10W 90/00; H10W 90/724; H10W 90/734

(57) ABSTRACT

An interposer substrate includes a base substrate having first and second opposing surfaces, a through via penetrating the base substrate, and dummy vias penetrating the base substrate to form an identification mark on the second surface. A wiring structure is disposed on the first surface and electrically connected to the through via. A first conductive pad is disposed on the second surface and electrically connected to the through via. The dummy vias are electrically isolated from the wiring structure and conductive pad.

### CROSS-REFERENCE TO RELATED APPLICATION

This application claims priority to and the benefit of Korean Patent Application No. 10-2025-0018053 filed with the Korean Intellectual Property Office on February 12, 2025, the entire contents of which are incorporated herein by reference.

### BACKGROUND OF THE INVENTION

### (a) Field of the Invention

The present disclosure relates to an interposer substrate and a semiconductor package including the same.

### (b) Description of the Related Art

An interposer substrate is disposed between semiconductor chips and a package substrate to provide electrical connection between the semiconductor chips and the package substrate and may function as an intermediate substrate for adjusting a wire pitch. Additionally, the interposer substrate may provide electrical connections between the semiconductor chips. The interposer substrate may include through vias for vertical connection between the semiconductor chips and the package substrate.

### SUMMARY OF THE INVENTION

In one aspect, the present disclosure attempts to provide an interposer substrate capable of wafer tracking through its lower surface and a semiconductor package including the same.

In another aspect, the present disclosure attempts to provide an interposer substrate that facilitates wafer commonality analysis and a semiconductor package including the same.

As one embodiment, the present disclosure provides an interposer substrate comprising: a base substrate having a first surface and a second surface which are opposite to each other; a through via that penetrates the base substrate; dummy vias penetrating the base substrate and providing an identification mark on the second surface of the base substrate; a wiring structure disposed on the first surface of the base substrate and electrically connected to the through via; and a first conductive pad disposed on the second surface of the base substrate and electrically connected to the through via.

As one embodiment, the present disclosure provides an interposer substrate comprising: a base substrate having a first surface and a second surface which are opposite to each other; a through via that penetrates the base substrate; dummy vias penetrating the base substrate and providing an identification mark on the second surface of the base substrate; a wiring structure including a wiring layer disposed on the first surface of the base substrate and electrically connected to the through via, an insulation layer covering the wiring layer, and a first conductive pad disposed on the insulation layer and electrically connected to the wiring layer; and a second conductive pad disposed on the second surface of the base substrate and electrically connected to the through via; wherein the dummy vias are disposed outside of the through via, the wiring layer, the first conductive pad and the second conductive pad in a plan view, and are electrically insulated with the through via, the wiring layer, the first conductive pad and the second conductive pad.

As one embodiment, the present disclosure provides a semiconductor package comprising: an interposer substrate; and semiconductor chips disposed on the interposer substrate and electrically connected to the interposer substrate; wherein the interposer substrate comprises: a base substrate having a first surface and a second surface which are opposite to each other; a through via that penetrates the base substrate; dummy vias penetrating the base substrate and providing an identification mark on the second surface of the base substrate; a wiring structure disposed on the first surface of the base substrate and electrically connected to the through via; and a conductive pad disposed on the second surface of the base substrate and electrically connected to the through via; and wherein the semiconductor chips are disposed on the wiring structure of the interposer substrate.

According to one aspect of the present disclosure, an interposer substrate capable of wafer tracking through its lower surface and a semiconductor package including the same can be provided.

According to another aspect of the present disclosure, an interposer substrate that facilitates wafer commonality analysis and a semiconductor package including the same can be provided.

### BRIEF DESCRIPTION OF THE DRAWINGS

FIG. 1 is a cross-sectional view of an interposer substrate according to one embodiment.

FIG. 2 is an enlarged view of region A of FIG. 1.

FIG. 3 is a bottom view of FIG. 1.

FIG. 4 is a cross-sectional view of an interposer substrate according to another embodiment.

FIG. 5 is a cross-sectional view of a semiconductor package according to one embodiment.

FIG. 6 is a cross-sectional view of a semiconductor package according to one embodiment.

FIG. 7 to FIG. 23 illustrate a manufacturing process of the semiconductor package illustrated in FIG. 6.

### DETAILED DESCRIPTION OF THE EMBODIMENTS

Hereinafter, with reference to the accompanying drawings, various embodiments of the present disclosure are described in detail so that a person of ordinary skill in the art to which the present disclosure pertains can easily practice the present disclosure. The present disclosure may be implemented in many different forms and is not limited to the embodiments described herein.

To clearly explain the present disclosure, parts that are not related to the explanation have been omitted, and the same reference symbols are used for identical or similar components throughout the specification.

In addition, the size and thickness of each component shown in the drawings are arbitrarily shown for better understanding and ease of description, so the present disclosure is not necessarily limited to what is shown. In the drawings, the thickness of layers, films, panels, regions, etc., is exaggerated for clarity. And in the drawing, for better understanding and ease of description, the thickness of some layers and regions is exaggerated.

Throughout the specification, when it is described that an element is “connected” to another element, this includes not only cases where it is “directly connected” but also cases where it is “indirectly connected” through another member. From a similar perspective, this includes not only being “physically connected” but also being “electrically connected”.

Additionally, it will be understood that when an element such as a layer, film, region, or substrate is referred to as being “on” another element, it can be directly on another element or intervening elements may also be present. In contrast, when an element is referred to as being “directly on” another element, there are no intervening elements present. Also, being “above” or “on” the referenced part means being positioned above or below the referenced part, and does not necessarily mean being positioned “above” or “on” the opposite direction of gravity.

Additionally, unless explicitly described to the contrary, the word “comprise”, and variations such as “comprises” or “comprising”, will be understood to imply the inclusion of stated elements but not the exclusion of any other elements.

Also, throughout the specification, the phrase “in a plan view” means when an object portion is viewed from above, and the phrase “in a cross-sectional view” means when a cross-section taken by vertically cutting an object portion is viewed from the side.

Additionally, throughout the specification, the sequential numbers, such as first, second, etc., are used to distinguish a component from other identical or similar components, and are not necessarily intended to refer to a specific component. Thus, a component referred to as a first component in a particular part of the specification may be referred to as a second component in another part of the specification.

Additionally, throughout the specification, a singular reference to any component includes a plurality of references to that component, unless otherwise stated. For example, “insulation layer” can be used to mean not only one insulation layer, but also a plurality of insulation layers, such as two, three or more.

Additionally, throughout the specification, references to directions such as top, upper side, upper side, lower side, lower side, etc. are described to aid explanation and understanding based on the drawings.

Hereinafter, an interposer substrate and a semiconductor package including the same according to embodiments of the present disclosure are described with reference to the drawing.

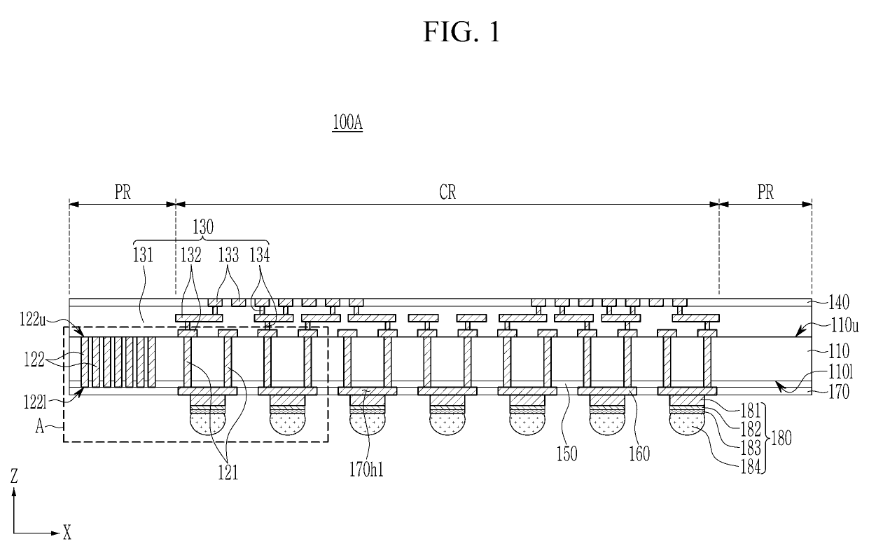

FIG. 1 is a cross-sectional view of an interposer substrate according to one embodiment.

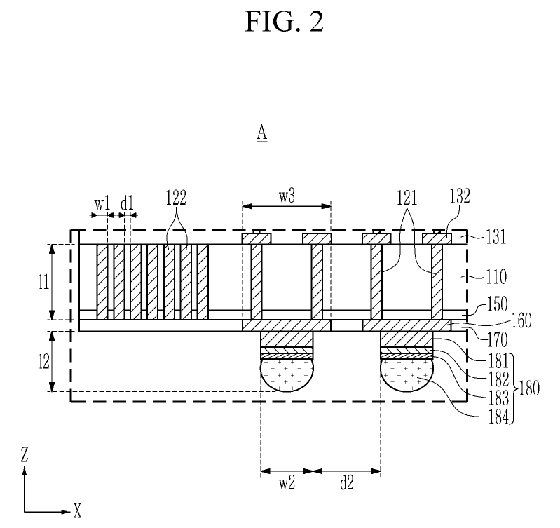

FIG. 2 is an enlarged view of region A of FIG. 1.

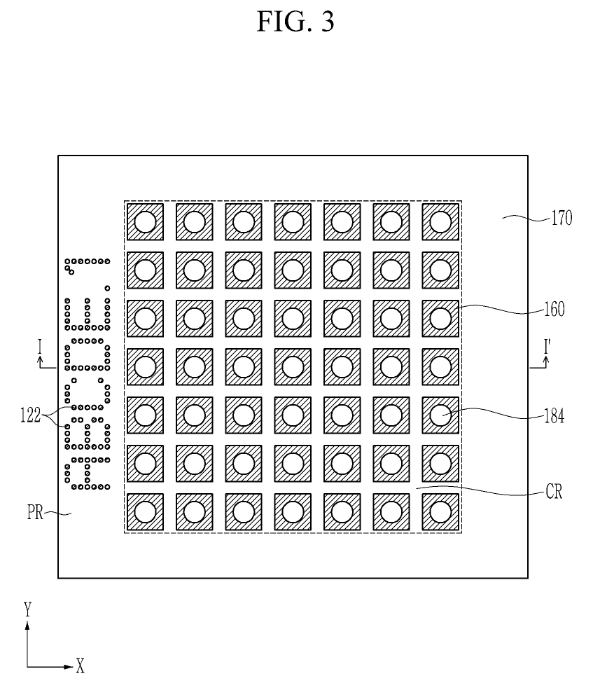

FIG. 3 is a bottom view of FIG. 1.

An interposer substrate 100A according to an embodiment includes a base substrate 110 having a first surface 110u and a second surface 110l which are opposite to each other, through vias 121 and dummy vias 122 penetrating the base substrate 110, a wiring structure 130 disposed on the first surface 110u of the base substrate 110 and electrically connected to the through vias 121, and a first conductive pad 160 disposed on the second surface 110l of the base substrate 110 and electrically connected to the through vias 121. Additionally, the interposer substrate 100A may further include at least one component of a first protective layer 140 disposed on the first surface 110u of a base substrate 110, an insulation film 150 disposed on the second surface 110l of the base substrate 110, a second protective layer 170 disposed on the insulation film 150, and a connection structure 180 disposed on the first conductive pad 160.

The interposer substrate 100A according to an embodiment may have a central region CR and a peripheral region PR surrounding the central region CR. The central region CR may mean a region where wires such as signal, power, and ground are designed. Each wire may include, for example, a first conductive pad 160, a through via 121, a wiring layer 132, and a second conductive pad 133 connected to each other. The peripheral region PR may be a KOZ (keep out zone), which is a region where wires are not designed. The central region CR and the peripheral region PR may not have boundaries that can be visually distinguished from each other.

The base substrate 110 can be extended to the central region CR and peripheral region PR of the interposer substrate 100A. The base material 110 may be formed by processing a wafer. For example, the base substrate 110 may be formed by forming other components of the interposer substrate 100A, such as through vias 121, to or on the wafer, packaging the wafer together with semiconductor chips, and then cutting the wafer into individual chip units. The base material 110 may include a semiconductor such as silicon (Si), germanium (Ge), or a compound semiconductor such as gallium arsenide (GaAs) or silicon carbide (SiC). However, the base material 110 may include other types of materials, such as organic insulating material and glass.

The through vias 121 penetrate in the Z direction between the first surface 110u and the second surface 110l of the base substrate 110, and may electrically connect the wiring structure 130 and the first conductive pad 160. The through vias 121 may be disposed in the central region CR of the interposer substrate 100A. A conductive material may be used as a forming material for the through via 121. For example, the through via 121 may include a metal or an alloy of metals, such as copper (Cu), aluminum (Al), tungsten (W), titanium (Ti), or tantalum (Ta). If necessary, an insulating barrier film may be additionally interposed between the through via 121 and the base substrate 110 in a form of surrounding the through via 121.

The dummy vias 122 may penetrate in the Z direction between the first face 110u and the second face 110l of the base material 110. The dummy vias 122 may provide an identification mark on the second surface 110l of the base substrate 110 (e.g., at the lower surface of the interposer substrate 100A). The third surface 122u of the dummy via 122 may be coplanar with the first surface 110u of the base substrate 110. Additionally, the fourth surface 122l of the dummy via 122 protrudes downward from the second surface 110l of the base substrate 110, and the region protruded from the base substrate 110 may be embedded in the insulation film 150. The fourth surface 122l of the dummy via 122 may be coplanar with the lower surface of the insulation film 150.

Dummy vias 122 may be disposed in the peripheral region PR of the interposer substrate 100A. The dummy vias 122 may also be understood as being disposed outside of components, for example, the through via 121, the wiring layer 132, the second conductive pad 133 and via 134 of the wiring structure 130, the first conductive pad 160, and the connection structure 180, which are disposed in the central region CR of the interposer substrate 100A. The dummy vias 122 may be electrically insulated from the through via 121, the wiring structure 130 (the wiring layer 132, the second conductive pad 133 and the via 134 of the wiring structure 130) and the first conductive pad 160. By forming the dummy vias 122 in the peripheral region PR of the interposer substrate 100A, the dummy vias 122 may be formed without changing a wire design.

The dummy vias 122 may have, but are not limited to, a circular cylinder shape or a polygonal prism shape such as a square prism or a hexagonal prism.

The maximum cross-sectional width w1 (e.g., diameter when dummy via 122 has a circular cylinder shape) of each dummy via 122 may be 1 µm or more and 30 µm or less. If the maximum cross-sectional width w1 of each dummy via 122 is less than 1 µm, it may be difficult to clearly recognize the identification mark, and if the maximum cross-sectional width w1 of each dummy via 122 is greater than 30 µm, it may be difficult to form a plurality of dummy vias 122 to provide the identification mark, or an increase in a size of the interposer substrate 100A may be required.

The distance d1 between the dummy vias 122 may be 1 µm or more and 100 µm or less. If the distance d1 between the dummy vias 122 is less than 1 µm, problems such as increased process difficulty may occur, and if the distance d1 between the dummy vias is greater than 100 µm, it may be difficult to form a plurality of dummy vias 122 to provide an identification mark, or an increase in a size of the interposer substrate 100A may be required.

The dummy vias 122 may be formed through the same process as the through vias 121, and the cross-sectional width of the dummy via 122 may be the same as the cross-sectional width of the through via 121. If the dummy vias 122 and the through vias 121 are formed through the same process, a separate process for forming the dummy vias 122 may not be required. Depending on the embodiment, the cross-sectional width of the dummy via 122 may be formed narrower than the cross-sectional width of the through via 121, and an identification mark of a complex shape may be provided through the dummy vias 122 having a fine width. Alternatively, the cross-sectional width of the dummy via 122 may be formed wider than the cross-sectional width of the through via 121.

The length l1 of the dummy vias 122 in the Z direction may be 10 µm or more and 150 µm or less.

The identification mark provided by the dummy vias 122 may include at least one of alphabets (uppercase and lowercase letters), numbers, and symbols. Symbols may include, for example, periods (.), commas (,), quotation marks (' and “), hyphens (-), underscores (_), tildes (-), colons (:), and semicolons (;).

A conductive material may be used as a forming material for the dummy via 122. For example, dummy via 122 may include a metal or an alloy of metals such as copper (Cu), aluminum (Al), tungsten (W), titanium (Ti), or tantalum (Ta). An insulating barrier film may be additionally interposed between the dummy via 122 and the base substrate 110 in a form of surrounding the dummy via 122.

The wiring structure 130 may include a wiring layer (or wiring layers) 132, an insulation layer 131 covering the wiring layer 132, and a second conductive pad 133 disposed on the insulation layer 131 and electrically connected to the wiring layer 132. The wiring layers 132 disposed in different layers or the wiring layer 132 and the second conductive pad 133 may be electrically connected through a via 134 embedded in the insulation layer 131.

The insulation layer 131 may be extended to the central region CR and peripheral region PR of the interposer substrate 100A, and the wiring layer 132, via 134, and second conductive pad 133 may be disposed in the central region CR of the interposer substrate 100A.

The insulation layer 131 may cover the third surface 122u exposed through the first surface 110u of the base substrate 110 of the dummy vias 122. The insulation layer 131 may be formed of an insulating material. For example, the insulation layer 131 may include an inorganic insulating material such as silicon oxide (SiO₂), silicon nitride (Si₃N₄), a thermoplastic resin such as polyimide (PI), or a thermosetting resin such as epoxy. The insulation layer 131 may also include a photo-imageable dielectric (PID) capable of forming a photo via.

The wiring layer 132 may include wiring patterns that constitute signal wires for signal transmission, power wires for power supply, and ground wires for providing ground. The wiring layer 132 may be electrically connected to the through via 121 and may include a via pad connected to the through via 121. The via pad of wiring layer 132 may be formed directly on the first surface 110u of the base substrate 110.

The second conductive pad 133 may provide an electrical connection between the interposer substrate 100A and another component, for example, a semiconductor chip disposed on the interposer substrate 100A. The second conductive pad 133 may have a shape such as, but not limited to, a square, rectangular shape, a circle, or an oval shape in a plan view.

The via 134 may have a circular cylinder shape, a tapered shape with a width that narrows in a direction from one side to the other side, etc. The via 134 may be integrally formed with the wiring layer 132 formed on its upper side and may not have a boundary with the wiring layer 132.

A conductive material may be used as each material of the wiring layer 132, the second conductive pad 133, and the via 134. For example, the wiring layer 132, the second conductive pad 133, and the via 134 may each include a metal such as aluminum (Al), copper (Cu), tungsten (W), gold (Au), platinum (Pt), silver (Ag), tin (Sn), chromium (Cr), palladium (Pd), or an alloy of two or more of these.

The first protective layer 140 may be disposed on the wiring structure 130. For example, the first protective layer 140 may be disposed on the insulation layer 131 of the wiring structure 130 and may have an opening that exposes at least a portion of the second conductive pad 133. For example, the first protective layer 140 may have an opening that is at least partially filled with the second conductive pad 133. Alternatively, the first protective layer 140 may extend onto the second conductive pad 133 to cover an edge region of the upper surface of the second conductive pad 133, and an opening of the first protective layer 140 may be disposed on the upper surface of the second conductive pad 133 to expose a center region of the upper surface of the second conductive pad 133. The first protective layer 140 may be extended to the central region CR and peripheral region PR of the interposer substrate 100A. Insulating material may be used as a material for the first protective layer 140.

In some embodiment, an additional identification mark may be formed on the first surface 110u of the base substrate 110. The additional identification mark may be formed, for example, on the first surface 110u of the base substrate 110, the upper surface of the wiring structure 130 or the upper surface of the first protective layer 140. The additional identification mark may enable tracking of the base substrate 110 during the manufacturing process together with the identification mark provided by the dummy vias 122 on the second surface 110l of the base substrate 110.

The insulation film 150 may be disposed on the second surface 110l of base substrate 110. The insulation film 150 may be extended to the central region CR and peripheral region PR of the interposer substrate 100A. The through via 121 and the dummy vias 122 may penetrate the insulation film 150, and the first conductive pad 160 may be disposed on the insulation film 150. The insulation film 150 may include an insulating material such as silicon oxide (SiO₂) or silicon nitride (Si₃N₄).

Each first conductive pad 160 may be connected to a single through via 121 or may be connected to a plurality of through vias 121. The first conductive pads 160 may be disposed in the central region CR of the interposer substrate 100A. A conductive material may be used as a material for the first conductive pad 160. For example, the first conductive pad 160 may include a metal such as aluminum (Al), copper (Cu), tungsten (W), gold (Au), platinum (Pt), silver (Ag), tin (Sn), chromium (Cr), palladium (Pd) or an alloy of two or more of these. The first conductive pad 160 may have a shape such as, but not limited to, a square, rectangular shape, circular or oval in a plan view. The maximum cross-sectional width w3 of the first conductive pad 160 may be 10 µm or more and 300 µm or less.

The second protective layer 170 may be disposed on the second surface 110l of the base substrate 110 and may have a first opening 170h1 exposing at least a portion of the first conductive pad 160. For example, the second protective layer 170 may have a first opening 170h1 that is at least partially filled with the first conductive pad 160. Alternatively, the second protective layer 170 may extend onto the first conductive pad 160 to cover an edge region of the lower surface of the first conductive pad 160, and a first opening 170h1 of the second protective layer 170 may be disposed on the lower surface of the first conductive pad 160 to expose an edge region of the lower surface of the first conductive pad 160. The second protective layer 170 may cover the fourth surface 122l exposed through the second surface 110l of the base substrate 110 of the dummy vias 122. The second protective layer 170 may be extended to the central region CR and peripheral region PR of the interposer substrate 100A. An insulating material may be used as a material for the second protective layer 170. Additionally, the second protective layer 170 may be transparent or translucent to ensure visibility of the dummy vias 122 that provide an identification mark. For example, PID may be used as a material for the second protective layer 170.

The connection structures 180 may provide electrical connection between the interposer substrate 100A and other components, for example, a package substrate on which the interposer substrate 100A is disposed. The connection structure 180 may include one or more conductive layers 181, 182, and 183 and conductive bumps 184 disposed on the conductive layers 181, 182, and 183. The conductive layers 181, 182, and 183 may be stacked to have a pillar shape and may be connected to the conductive bump 184 having a cap shape to form a pillar bump. However, the connection structure 180 may be formed having other structures such as a C4 bump.

A conductive material may be used as a material for each of the conductive layers 181, 182, and 183 and the conductive bump 184. The conductive layers may include, for example, a first conductive layer 181 including copper (Cu), a second conductive layer 182 including nickel (Ni), and a third conductive layer 183 including gold (Au). The second conductive layer 182 may prevent a formation of an inter-metallic compound (IMC) due to diffusion between the first conductive layer 181 and the conductive bump 184. Also, the third conductive layer 183 may prevent surface oxidation of a conductive pillar including the conductive layers 181, 182, and 183 and improve soldering quality and reliability. The conductive bump 184 may include solder formed of, for example, Sn-Ag alloy, Sn-Ag-Cu alloy, etc.

The maximum cross-sectional width w2 of the connection structure 180 may be 10 µm or more and 300 µm or less. The distance d2 between the connection structures 180 may be 40 µm or more and 500 µm or less. The length l2 in the Z direction of the connection structure 180 may be 20 µm or more and 120 µm or less.

Meanwhile, an upper surface where a wiring structure of an interposer substrate is positioned may be covered by a carrier structure attached to the interposer substrate during a manufacturing process. Additionally, in a packaging process using an interposer substrate, the upper surface of the interposer substrate may be covered by an encapsulant covering semiconductor chips. Therefore, wafer tracking through an identification mark provided on the upper surface of the interposer substrate (e.g., formed at the upper surface of the wafer) may be difficult. In addition, after a packaging process, where semiconductor chips are disposed and molded on a wafer-level interposer substrate and then the wafer-level package is cut into individual chip units through a sawing process, it may be more difficult to track the lot to which the individual chip unit wafer belongs.

According to the present disclosure, by forming dummy vias that provide an identification mark on the wafer, wafer tracking through the lower surface of the wafer is possible after attachment of a carrier structure, formation of an encapsulant, and even after a sawing process. Wafer tracking during the manufacturing process may facilitate wafer commonality analysis, which may identify and improve wafer defect-causing factors (e.g., process, equipment, lot, etc.) and improve manufacturing yield.

The dummy vias providing an identification mark of the present disclosure may be applied not only to an interposer substrate including through vias, but also to a semiconductor chip, semiconductor package, etc. including through vias, and such embodiments should also be considered to be included in the present disclosure.

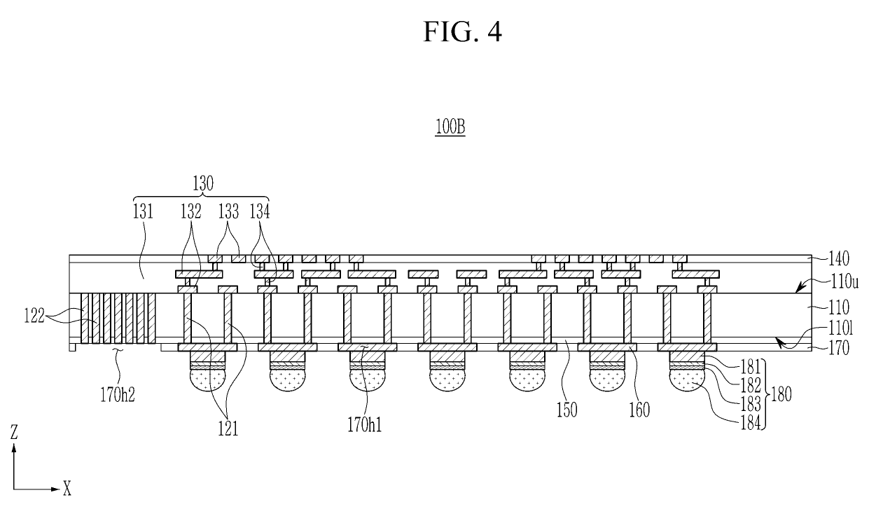

FIG. 4 is a cross-sectional view of an interposer substrate according to another embodiment.

According to another embodiment, the second passivation layer 170 of the interposer substrate 100B may further have a second opening 170h2 exposing the dummy vias 122. When the second protective layer 170 is formed of an opaque material, the second opening 170h2 may be formed to ensure visibility of the dummy vias 122 providing an identification mark on the lower surface of the interposer substrate 100B.

For other configurations, the same details as described above for the interposer substrate 100A according to one embodiment of the present disclosure may be equally applied.

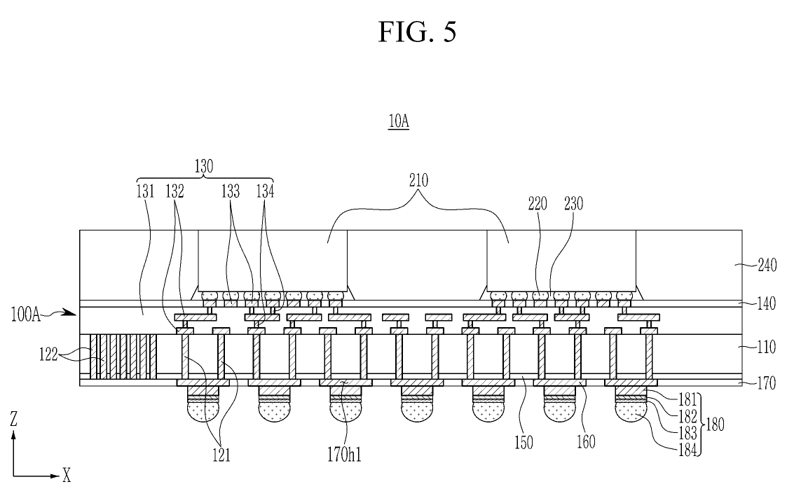

FIG. 5 is a cross-sectional view of a semiconductor package according to one embodiment.

A semiconductor package 10A according to an embodiment includes the interposer substrate 100A and semiconductor chips 210 disposed on the interposer substrate 100A and electrically connected to the interposer substrate 100A. Additionally, the semiconductor package 10A may further include an encapsulant 240 covering at least a portion of each of the semiconductor chips 210.

The interposer substrate 100A may include dummy vias 122 according to the present disclosure. Interposer substrate 100A may of course be the interposer substrate 100B as shown in FIG. 4.

The semiconductor chips 210 may be disposed on the wiring structure 130 of the interposer substrate 100A and electrically connected to the interposer substrate 100A through the second conductive pads 133. Each of the semiconductor chips 210 may be connected to the interposer substrate 100A via connection structures 220, and the connection structures 220 may be covered with underfill resin 230. Since the dummy vias 122 are disposed outside of the second conductive pads 133 that are connected to the semiconductor chips 210 in a plan view, the dummy vias 122 may also be understood as being disposed outside of the semiconductor chips 210.

The type of each of the semiconductor chips 210 is not particularly limited and may include logic chips and/or memory chips. The logic chip may include at least one of an application processor (AP), a microprocessor, a central processing unit (CPU), a graphic processing unit (GPU), a neural processing unit (NPU), an Application Specific Integrated Circuit (ASIC), and a System on Chip (SoC). The memory chip may include at least one of a high bandwidth memory (HBM) chip, a DRAM (dynamic random access memory) chip, a SRAM (static random access memory) chip, a flash memory chip, a ROM (read-only memory) chip, and an MRAM (magnetic random access memory) chip. The types of semiconductor chips 210 may be the same or different.

The encapsulant 240 may cover at least a portion of each of the semiconductor chips 210 on the interposer substrate 100A. The upper surface of the semiconductor chips 210 may not be covered with the encapsulant 240. The upper surface of the semiconductor chips 210 and the upper surface of the encapsulant 240 may be coplanar. The heat dissipation characteristics of the semiconductor package 10A may be improved by not covering the upper surface of the semiconductor chips 210 with the encapsulant 240. As a material of encapsulant 240, an insulating material such as epoxy molding compound (EMC) may be used.

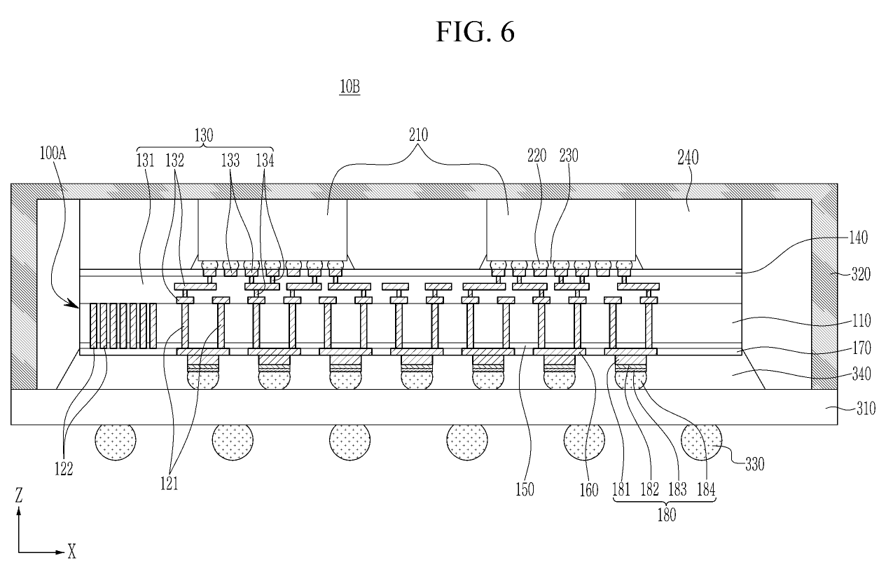

FIG. 6 is a cross-sectional view of a semiconductor package according to one embodiment.

The semiconductor package 10A illustrated in FIG. 5 may be mounted on a package substrate 310 in a sub-package form to provide a semiconductor package 10B.

The semiconductor package 10B includes a package substrate 310 and a semiconductor package 10A disposed on the package substrate 310, and may further include a heat dissipation structure 320.

The package substrate 310 on which the semiconductor package 10A is mounted may be a printed circuit board (PCB). The semiconductor package 10A may be physically and electrically connected to the package substrate 310 through the connection structures 180, and the connection structures 180 may be covered with underfill resin 340. Connection structures 330 including a conductive material such as solder may be disposed on the lower surface of the package substrate 310, and the package substrate 310 may be mounted on another component, such as a main substrate, via the connection structures 330.

A heat dissipation structure 320 may be disposed (e.g., attached) on the package substrate 310 and surround a side surface of the semiconductor package 10A and cover an upper surface of the semiconductor package 10A. The heat dissipation structure 320 may be connected to the semiconductor chips 210 of the semiconductor package 10A to form a heat dissipation path toward an upper side. Depending on the embodiment, a thermal interface material (TIM) may be disposed between the semiconductor chips 210 and the heat dissipation structure 320. A gap may exist between the heat dissipation structure 320 and the side of the semiconductor package 10A. A material with high thermal conductivity may be used as a material for the heat dissipation structure 320. For example, the heat dissipation structure 320 may include a metal such as aluminum (Al), copper (Cu), tungsten (W), gold (Au), platinum (Pt), silver (Ag), tin (Sn), chromium (Cr), palladium (Pd), or an alloy of two or more of these.

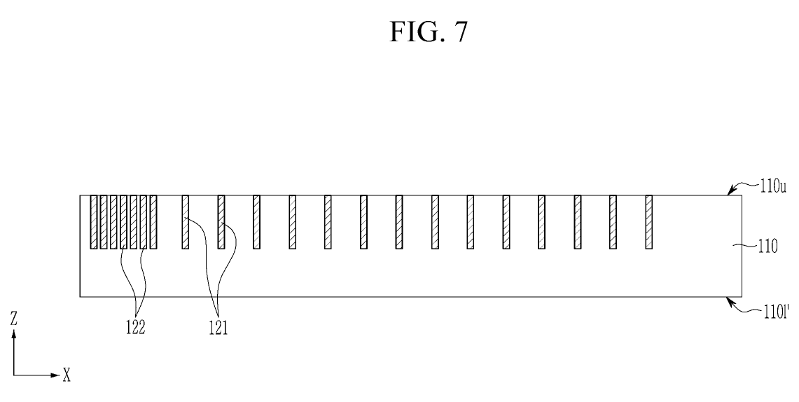

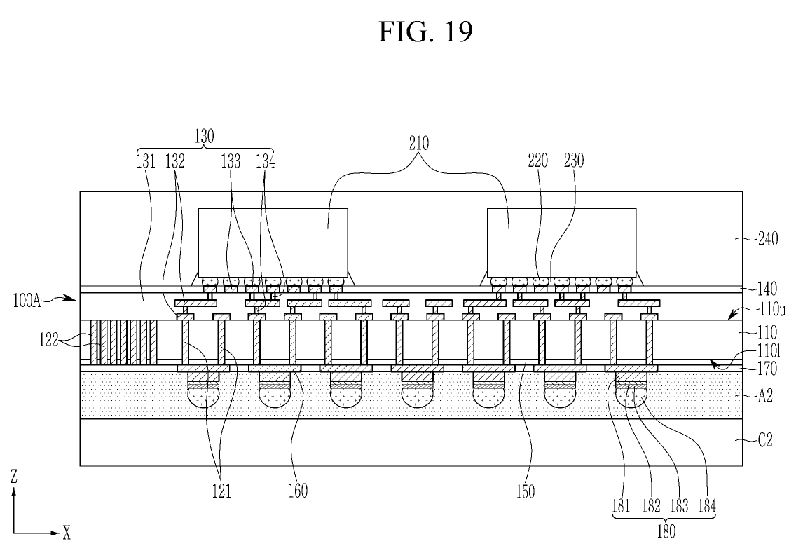

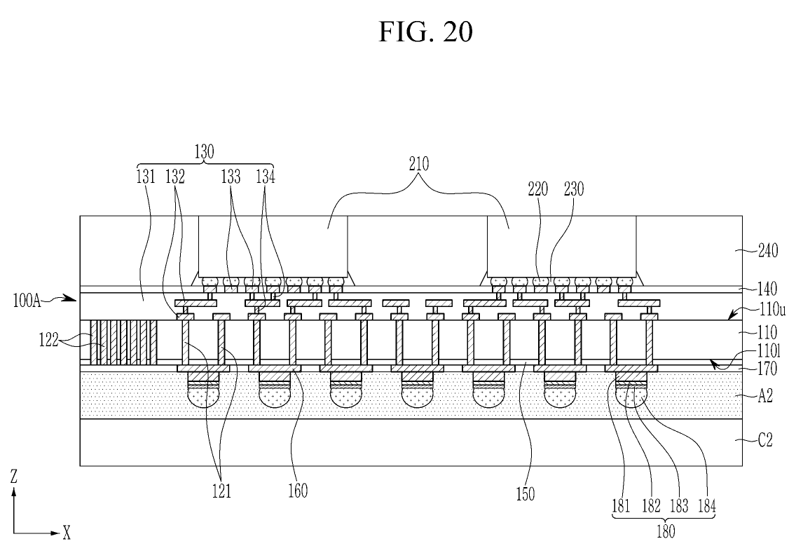

FIG. 7 to FIG. 23 illustrate a manufacturing process of the semiconductor package illustrated in FIG. 6.

First, referring to FIG. 7, through vias 121 and dummy vias 122 may be formed in a direction from the first surface 110u toward a second surface 110l', which is a surface before processing, of the base substrate 110. The second surface 110l' before processing of the base substrate 110 may be processed later, and in the present disclosure, different symbols were used for the second surface 110l' before processing of the base substrate 110 and the second surface 110l after processing of the base substrate 110. The formed through vias 121 and dummy vias 122 are embedded in the base substrate 110, and each upper surface may be exposed to the first surface 110u of the base substrate 110.

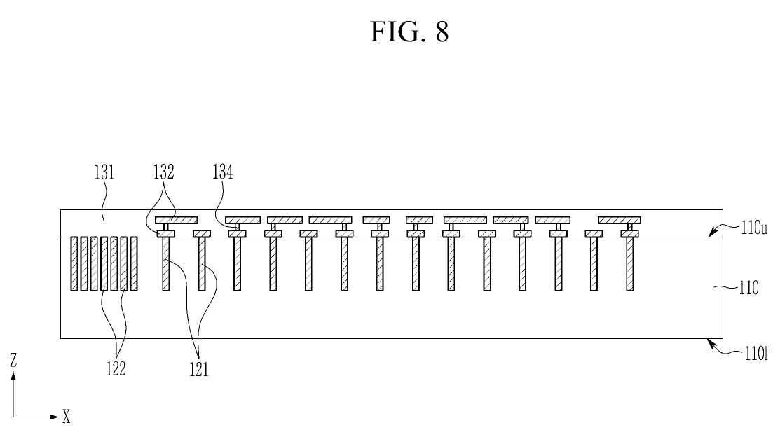

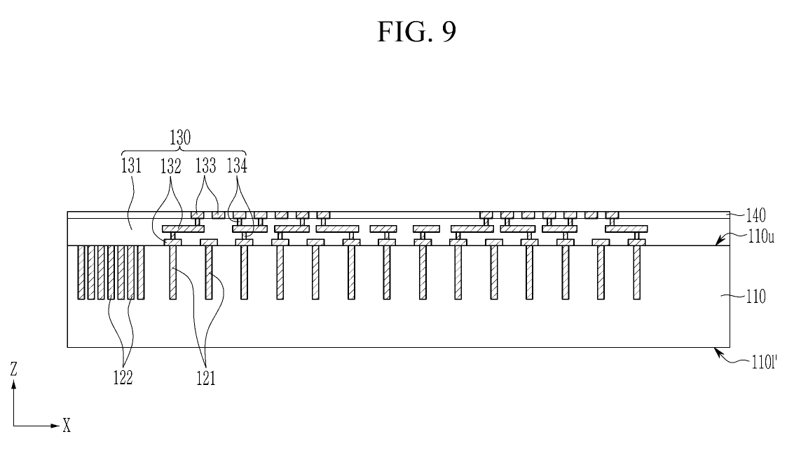

Next, referring to FIG. 8 and FIG. 9, a wiring structure 130 and a first protective layer 140 electrically connected to the through vias 121 may be formed on the first surface 110u of the base substrate 110. The first protective layer 140 may be formed on the insulation layer 131, and at least a portion of a region covering the second conductive pad 133 of the first protective layer 140 may be removed.

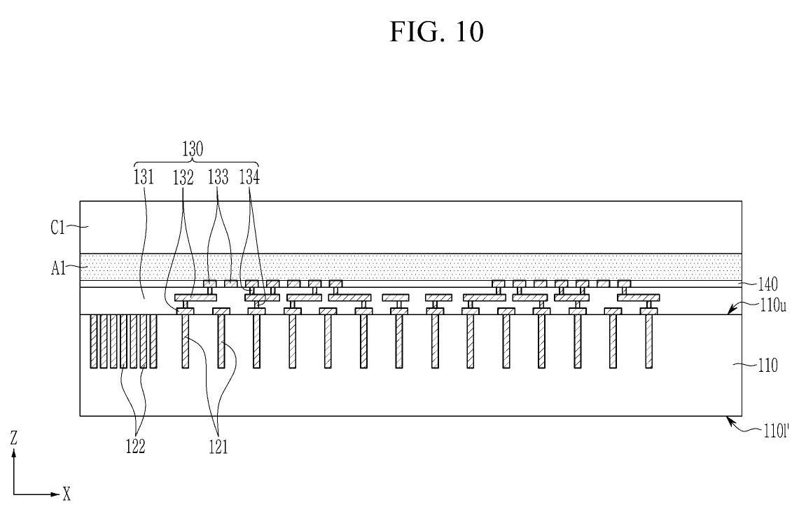

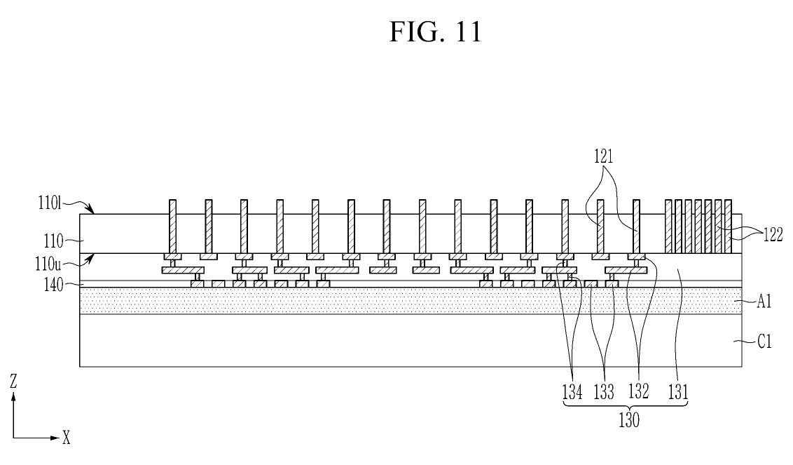

Next, referring to FIG. 10 and FIG. 11, a first carrier structure C1 may be attached through a first adhesive member A1 on the first protective layer 140, and the second surface 110l' of the base material 110 may be processed to form the second surface 110l. The second surface 110l' of the base substrate 110 may be processed by grinding and/or selective etching, and a portion of the base substrate 110 may be removed by the processing.

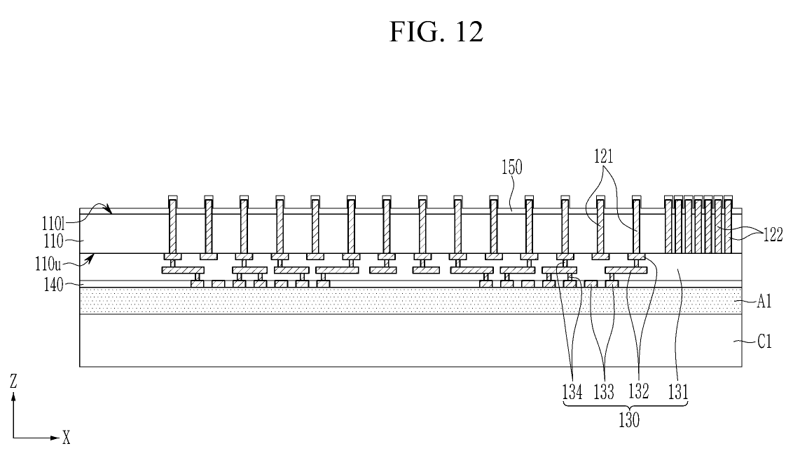

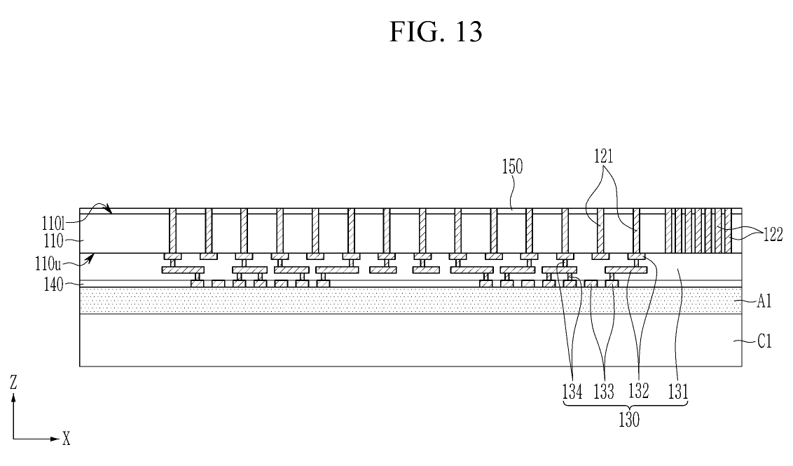

Next, referring to FIG. 12 and FIG. 13, An insulation film 150 may be formed along the second surface 110l of the base substrate 110, the surface of the through vias 121 and the dummy vias 122. Additionally, a portion of each of the insulation film 150, the through vias 121, and the dummy vias 122 may be removed to expose the through vias 121 and the dummy vias 122. The insulation film 150 may be formed by physical vapor deposition (PVD), chemical vapor deposition (CVD), atomic layer deposition (ALD), etc. A portion of each of the insulation film 150, the through vias 121 and the dummy vias 122 may be removed by chemical mechanical polishing (CMP).

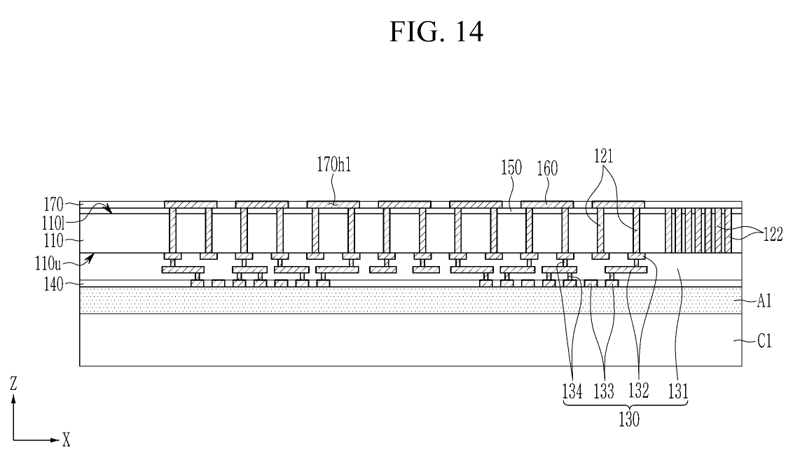

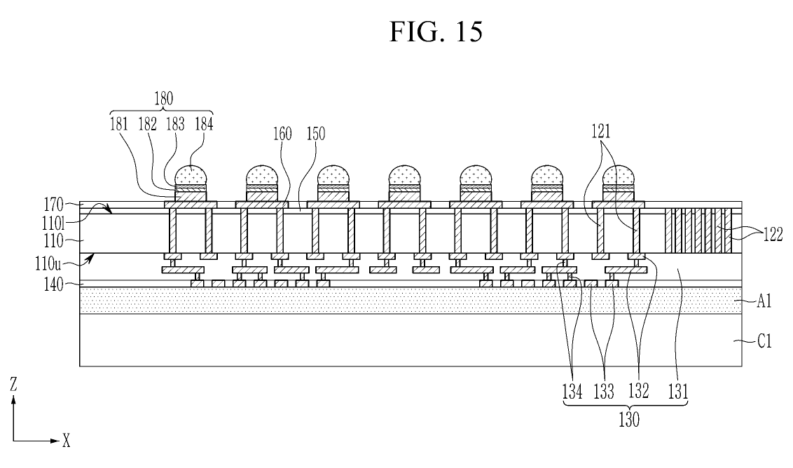

Next, referring to FIG. 14 and FIG. 15, first conductive pads 160 and a second protective layer 170 may be formed, and connection structures 180 may be formed on the first conductive pads 160. The first conductive pads 160 and the second protective layer 170 may be formed on the insulation film 150, and at least a portion of a region of the second protective layer 170 covering the first conductive pad 160 may be removed.

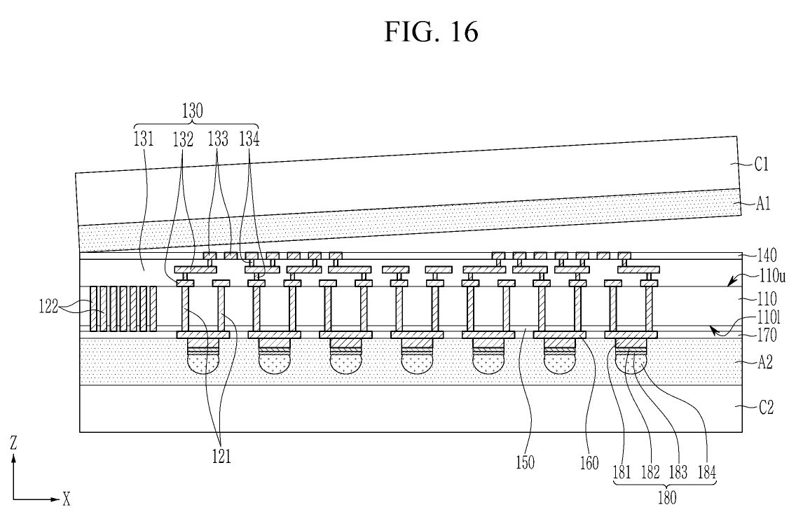

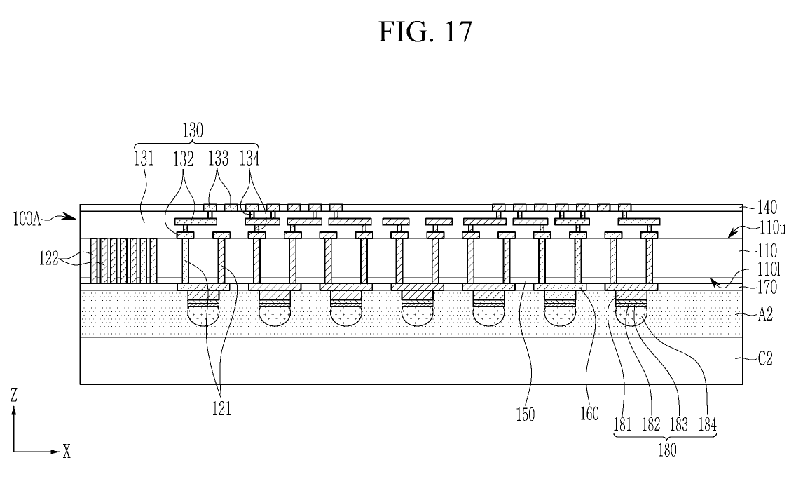

Next, referring to FIG. 16 and FIG. 17, a second carrier structure C2 is attached through a second adhesive member A2 on the connection structures 180 and the second protective layer 170, and the first carrier structure C1 and the first adhesive member A1 are separated from the first protective layer 140, thereby providing an interposer substrate 100A disposed on the second carrier structure C2. The first carrier structure C1 and the first adhesive member A1 may be separated from the first protective layer 140 by heat treatment, ultraviolet ray treatment, etc of the first adhesive member A1.

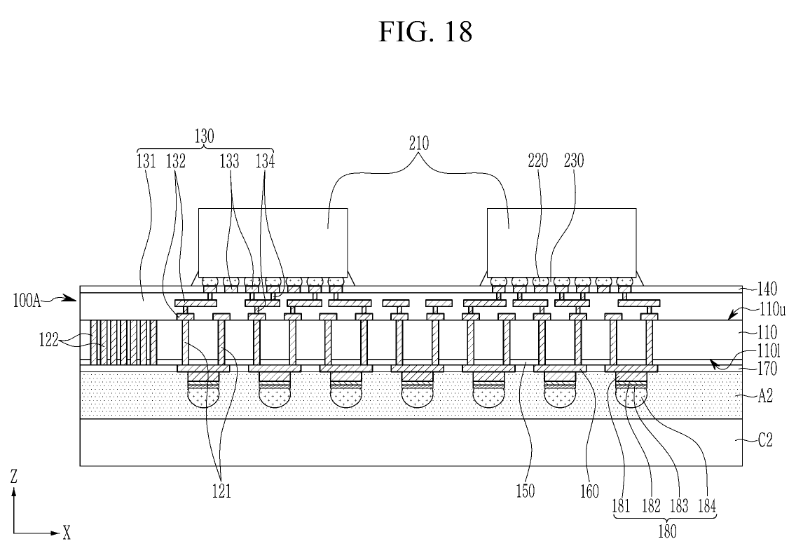

Next, referring to FIG. 18 to FIG. 20, semiconductor chips 210 may be disposed on the wiring structure 130 of the interposer substrate 100A, and encapsulated with an encapsulant 240. If necessary, an additional process of grinding an upper surface of the encapsulant 240 to expose an upper surface of each of the semiconductor chips 210 may be performed.

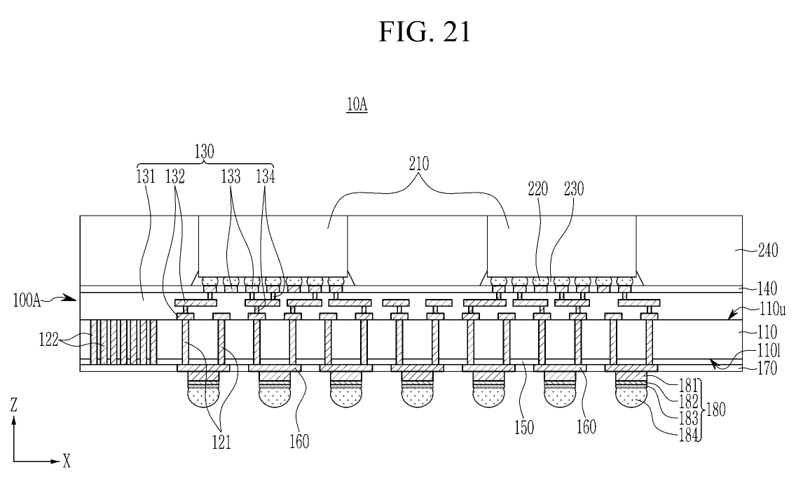

Next, referring to FIG. 21, the second carrier structure C2 and the second adhesive member A2 may be separated from the connection structures 180 and the second protective layer 170, thereby providing a semiconductor package 10A including the interposer substrate 100A. The second carrier structure C2 and the second adhesive member A2 may be separated by heat treatment, ultraviolet ray treatment, etc of the second adhesive member A2 from the connection structures 180 and the second protective layer 170.

The semiconductor package 10A may be formed at a wafer level, and an additional sawing process may be performed to cut the wafer level package into individual chip units.

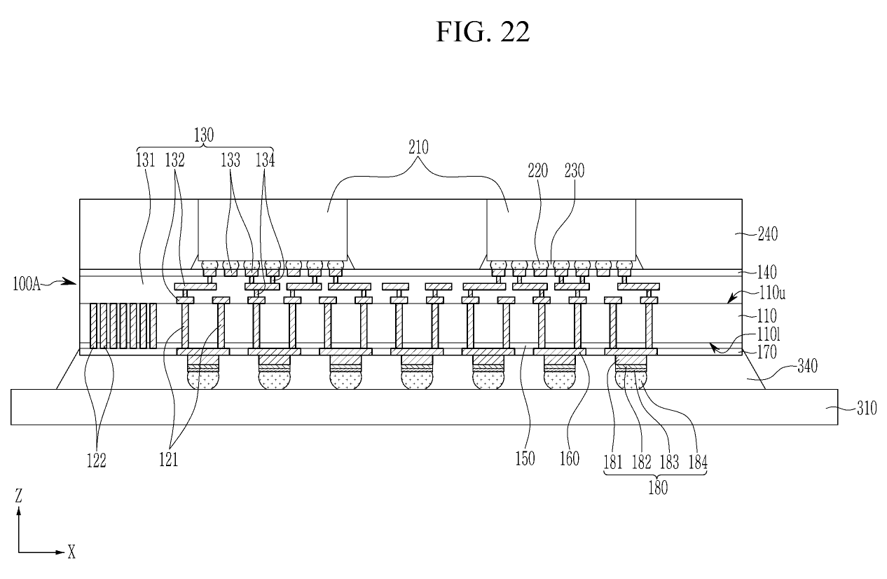

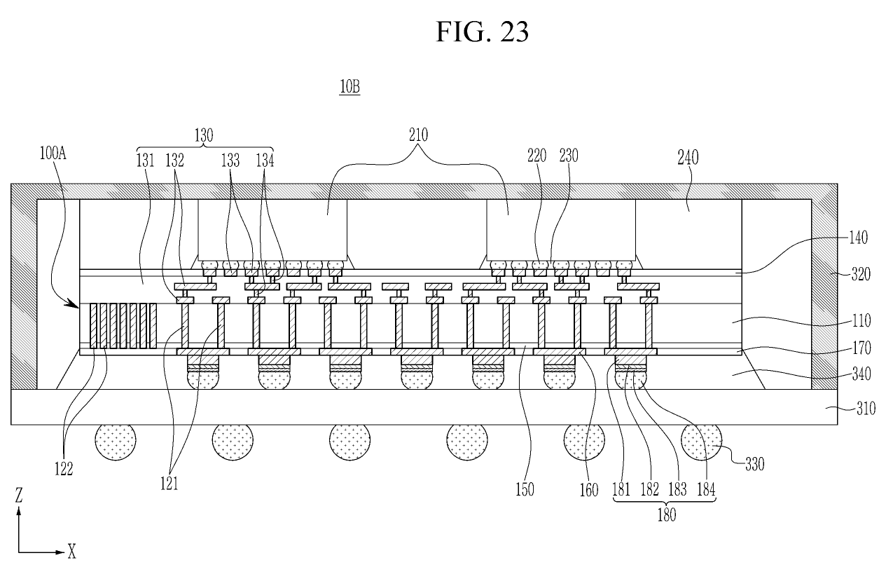

Next, referring to FIG. 22 and FIG. 23, the semiconductor package 10A may be disposed on a package substrate 310, and a heat dissipation structure 320 and connection structures 330 may be attached to the package substrate 310 to provide a semiconductor package 10B.

Although the embodiment of the present disclosure has been described in detail above, the scope of the present disclosure is not limited thereto, and various modifications and improvements of a person of an ordinary skill in the art utilizing the basic concept of the present disclosure defined in the following claims also fall within the scope of the present disclosure.

Additionally, the embodiments of the present disclosure are not independent of each other and may be implemented in combination with each other unless specifically contradictory. Accordingly, the combined embodiment of the present disclosure should also be considered as included in the present disclosure.

What is claimed is:

1. An interposer substrate comprising:
a base substrate having a first surface and a second surface which are opposite to each other;
a through via that penetrates the base substrate;
dummy vias penetrating the base substrate and providing an identification mark on the second surface of the base substrate;
a wiring structure disposed on the first surface of the base substrate and electrically connected to the through via; and
a first conductive pad disposed on the second surface of the base substrate and electrically connected to the through via.

2. The interposer substrate of claim 1,
wherein the through via and the first conductive pad are disposed in a central region of the interposer substrate, and the dummy vias are disposed in a peripheral region surrounding the central region of the interposer substrate.

3. The interposer substrate of claim 1,
wherein the dummy vias are electrically insulated from the wiring structure and the first conductive pad.

4. The interposer substrate of claim 1,
wherein the wiring structure includes a wiring layer, an insulation layer covering the wiring layer, and a second conductive pad disposed on the insulation layer and electrically connected to the wiring layer.

5. The interposer substrate of claim 4,
wherein the wiring layer and the second conductive pad are disposed in a central region of the interposer substrate, and the dummy vias are disposed in a peripheral region surrounding the central region of the interposer substrate.

6. The interposer substrate of claim 4,
wherein the insulation layer covers a third surface of each dummy via exposed through the first surface of the base substrate.

7. The interposer substrate of claim 1, further comprising:
a protective layer disposed on the second surface of the base substrate and having a first opening exposing the first conductive pad.

8. The interposer substrate of claim 7,
wherein the protective layer covers a fourth surface of each dummy via exposed through the second surface of the base substrate,
and the protective layer is transparent or translucent.

9. The interposer substrate of claim 7,
wherein the protective layer has a second opening exposing the dummy vias.

10. The interposer substrate of claim 7,
wherein the protective layer includes a photo-imageable dielectric.

11. The interposer substrate of claim 7, further comprising:
an insulation film disposed on the second surface of the base substrate;
and wherein the through via and the dummy vias penetrate the insulation film, and the first conductive pad is disposed on the insulation film.

12. The interposer substrate of claim 1, further comprising:
a connection structure disposed on the first conductive pad.

13. The interposer substrate of claim 1,
wherein a maximum cross-sectional width of each of the dummy vias is 1 µm or more and 30 µm or less.

14. The interposer substrate of claim 1,
wherein a distance between adjacent dummy vias is 1 µm or more and 100 µm or less.

15. The interposer substrate of claim 1,
wherein a length of each of the dummy vias in a direction in which the dummy vias penetrate the base substrate is 10 µm or more and 150 µm or less.

16. The interposer substrate of claim 1,
wherein the identification mark includes at least one of letters, numbers and symbols.

17. An interposer substrate comprising:
a base substrate having a first surface and a second surface which are opposite to each other;
a through via that penetrates the base substrate;
dummy vias penetrating the base substrate and providing an identification mark on the second surface of the base substrate;
a wiring structure including a wiring layer disposed on the first surface of the base substrate and electrically connected to the through via, an insulation layer covering the wiring layer, and a first conductive pad disposed on the insulation layer and electrically connected to the wiring layer; and
a second conductive pad disposed on the second surface of the base substrate and electrically connected to the through via;
wherein the dummy vias are disposed outside of the through via, the wiring layer, the first conductive pad and the second conductive pad in a plan view, and electrically insulated from the through via, the wiring layer, the first conductive pad and the second conductive pad.

18. A semiconductor package comprising:
an interposer substrate; and
semiconductor chips disposed on the interposer substrate and electrically connected to the interposer substrate;
wherein the interposer substrate comprises:
a base substrate having a first surface and a second surface which are opposite to each other;
a through via that penetrates the base substrate;
dummy vias penetrating the base substrate and providing an identification mark on the second surface of the base substrate;
a wiring structure disposed on the first surface of the base substrate and electrically connected to the through via; and
a conductive pad disposed on the second surface of the base substrate and electrically connected to the through via;
and wherein the semiconductor chips are disposed on the wiring structure of the interposer substrate.

19. The semiconductor package of claim 18, further comprising:
an encapsulant covering at least a portion of each of the semiconductor chips.

20. The semiconductor package of claim 18,
wherein the dummy vias are disposed outside of the semiconductor chips in a plan view.
